(19) United States
(12) Patent Application Publication
(10) Pub. No.: US 2026/0190898 A1
(43) Pub. Date: Jul. 2, 2026

(54) CIRCULATION DUCT STRUCTURE FOR A SEMICONDUCTOR PROCESSING SYSTEM

(71) Applicant: ASM IP Holding B.V., Almere (NL)

(72) Inventors: Takashi Hagino, Aso-ku (JP); Akira Maruyama, Tokyo (JP); Ryosuke Adachi, Tokyo (JP); Joongmin Lee, Tokyo (JP)

(21) Appl. No.: 19/430,877

(22) Filed: Dec. 23, 2025

Related U.S. Application Data
(60) Provisional application No. 63/739,019, filed on Dec. 26, 2024.

(51) Int. Cl. H10P 72/00; B01D 53/40; B01D 53/44; B01D 53/82

(52) U.S. Cl. CPC H10P 72/0402; B01D 53/40; B01D 53/44; B01D 53/82; B01D 2256/10; B01D 2257/70; B01D 2258/0216; H10P 72/0454

(57) ABSTRACT

A duct assembly for a semiconductor processing system is disclosed in accordance with at least one embodiment of the invention. The duct assembly is coupled to an equipment front end module (EFEM) and is configured to process a nitrogen (N₂) gas that passes through the EFEM. The duct assembly is designed such that a chemical filter for processing the N₂ gas can be removed without detaching the duct assembly from the EFEM. Benefits from the at least one embodiment of the invention include a reduced maintenance time.

### CROSS-REFERENCE TO RELATED APPLICATIONS

This application claims priority to U.S. Provisional Patent Application Ser. No. 63/739,019 filed Dec. 26, 2025 and titled CIRCULATION DUCT STRUCTURE FOR A SEMICONDUCTOR PROCESSING SYSTEM, the disclosure of which is hereby incorporated by reference in its entirety.

### FIELD OF INVENTION

The present disclosure generally relates to fabricating semiconductor devices. More particularly, the present disclosure relates to equipment front-end module for semiconductor processing systems employed to fabricate semiconductor devices.

### BACKGROUND OF THE DISCLOSURE

Semiconductor processing systems, such as semiconductor processing systems with cluster-type platforms, commonly include an equipment front-end module (EFEM). These systems conventionally also include circulation ducts. The circulation ducts help maintain air quality control within the cleanroom, regulate temperature, maintain a uniform level of oxygen, maintain a uniform humidity within the EFEM, and ensure proper ventilation as needed by the EFEM.

In conventional systems, these circulation ducts are placed on either side of the EFEM. Such a placement results in an increase of the EFEM footprint. Further, a chemical filter is placed within the EFEM, whereby circulation ducts on either side of the EFEM prevent direct access to the chemical filter. Accordingly, when the chemical filter needs to be replaced, the circulation duct structure has to be unscrewed, and the duct needs to be removed to access and remove the filter. Similarly, entering the mini-environment within the EFEM also requires removal of circulation ducts. Both of these processes increase the downtime during replacement and maintenance.

FIG. 1 illustrates a prior art system 10 as described above. The prior art system 10 includes a EFEM 20, a first circulation duct 30, a second circulation duct 40, a first extension section 50, and a second extension section 60. Inside the EFEM 20 is a mini-environment in which a nitrogen (N₂) gas is circulated. The first circulation duct 30 may provide a pathway in which a N₂ gas is exhausted from the mini-environment of the EFEM 20. The second circulation duct 40 also may provide a pathway in which N₂ gas is exhausted from the mini-environment of the EFEM 20.

A first extension section 50 may comprise additional components for operation of the EFEM 20, such as a cooling stage, a filter, or an aligner, for example. The second extension section 60 may also comprise additional components for operation of the EFEM 20, such as a cooling stage, a filter, or an aligner, for example. The configuration of the first circulation duct 30 and the second circulation duct 40 may be such that the first circulation duct 30 and the second circulation duct 40 may need to be removed in order to replace a chemical filter.

Accordingly, there is a need in the art for improved placement of circulation duct structures for semiconductor processing systems. The present disclosure provides a solution to this need.

### SUMMARY OF THE DISCLOSURE

A semiconductor processing system is disclosed in accordance with at least one embodiment of the invention. The semiconductor processing system comprises: one or more load ports configured to hold wafers; an equipment front end module having a wafer transfer robot to transfer wafers between one or more load ports and a load lock chamber; a chemical filter configured to filter out a gas flowing through the equipment front end module; and at least one circulation duct structure coupled to the equipment front end module; wherein the at least one circulation duct structure is installed at a location proximate to the one or more load ports; and wherein the chemical filter is unobstructed by the at least one circulation duct structure.

A duct assembly is disclosed in accordance with at least one embodiment of the invention. The duct assembly comprises: an equipment front end module (EFEM) having a wafer transfer robot to transfer wafers between one or more load ports and a load lock chamber, wherein the EFEM comprises: a filter section configured to hold a chemical filter; and a mini-environment door; an upper duct section coupled to the filter section; a vertical duct section coupled to the upper duct section and located proximate to the one or more load ports; and a lower duct section coupled to the vertical duct section, wherein the lower duct section is located proximate to the mini-environment door.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is an overhead view of a prior art substrate processing system;

FIG. 2 is an overhead view of a substrate processing system in accordance with embodiments described herein;

FIG. 3 is an perspective view of an EFEM in the substrate processing system in accordance with embodiments described herein;

FIG. 4 is a perspective view of a part of a circulation duct structure in the semiconductor duct assembly in accordance with embodiments described herein.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

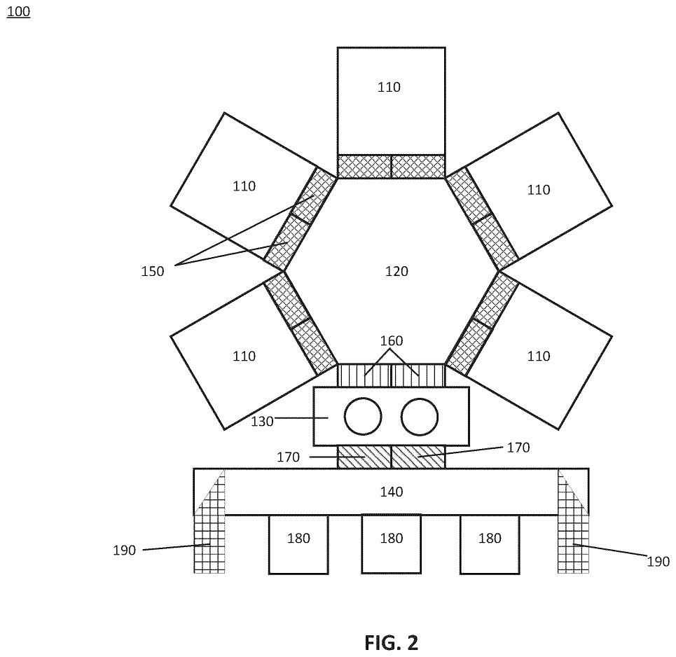

Reference will now be made to the drawings wherein like reference numerals identify similar structural features or aspects of the subject disclosure. For purposes of explanation and illustration, and not limitation, a partial view of a load lock arrangement coupling a process module to an equipment front-end module (EFEM) of a semiconductor processing system in accordance with the present disclosure is shown in FIGS. 2-4. The systems and methods of the present disclosure may be in semiconductor processing systems employed to fabricate semiconductor devices, such as in semiconductor processing systems employed to deposit material layers using chemical vapor deposition (CVD) and atomic layer deposition (ALD) techniques during the fabrication of logic and memory devices, though the present disclosure is not limited to any semiconductor processing operation or to the fabrication of any particular semiconductor device in general.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Wafers may be 200 millimeters in diameter, 300 millimeters, or even 450 millimeters in diameter. Substrates may be formed from one or more semiconductor materials including by way of non-limiting example silicon, silicon germanium, silicon oxide, gallium arsenide, gallium nitride and silicon carbide.

Referring to FIG. 2, an overhead view of a semiconductor processing system 100 is shown. The semiconductor processing system 100 may include at least one process module 110, a back-end transfer module 120, and a load lock arrangement 130. The semiconductor processing system 100 also may include an equipment front-end module (EFEM) 140, a processor, and an evacuation source. In the illustrated example, the semiconductor processing system 100 may include a cluster-type platform with five process modules 110 configured to deposit a material layer onto a substrate by an atomic layer deposition (ALD), a plasma enhanced atomic layer deposition (PEALD), a chemical vapor deposition (CVD), a plasma enhanced chemical vapor deposition (PECVD), an epitaxial deposition, or a physical vapor deposition (PVD). This is for illustration and description purposes only and is non-limiting. As will be appreciated by those of skill in the art in view of the present disclosure, semiconductor processing systems configured for other material layer deposition operations as well as semiconductor processing systems configured for processing operations other than material layer deposition (e.g., etching, rapid thermal processing) can also benefit from the present disclosure.

The at least one process module 110 may be coupled to the back-end transfer module 120 by at least one process module gate valve 150. The process module 110 further includes at least one process chamber. In some examples, the process module 110 may include more than one process chamber, such as a dual chamber module or a quad chamber module, for example. The process chamber(s) may be configured to flow a material layer precursor or reactant across the substrate during deposition of a material layer onto the substrate. A reactant source may be fluidly coupled to the process chamber of the process module to provide the reactant to the process chamber for deposition of the material layer on to the substrate.

The process module gate valve 150 may be configured to permit transfer of the substrate between the back-end transfer module 120 and the process module 110 before and after deposition of the material layer onto the substrate. In certain examples, the material layer may be deposited using an ALD or a CVD deposition technique. In some examples, the material layer may be deposited using a plasma enhanced ALD (PEALD) or a plasma enhanced CVD (PECVD) technique.

The back-end transfer module 120 is coupled to the load lock arrangement 130 and includes a back-end chamber body and a back-end substrate transfer robot. The back-end transfer module 120 is further coupled to the load lock arrangement 130 via a back-end gate valve 160. The back-end gate valve 160 may be configured to permit transfer of one or more substrates between the load lock arrangement and back-end transfer module.

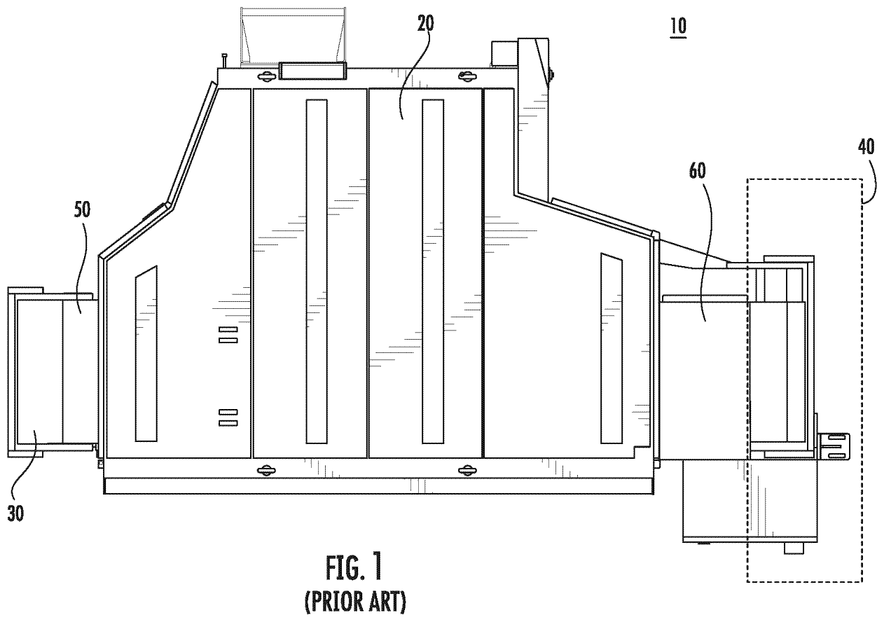

As shown in FIG. 1, load lock arrangement includes a load lock arrangement back-end facet. The back-end gate valve 160 is coupled to the load lock arrangement 130 at a load lock arrangement back-end facet, and the back-end gate valve 160 is further coupled to back-end transfer module 120 at a back-end transfer module facet. Accordingly, the load lock arrangement 130 is coupled to the back-end transfer module 120 using the back-end gate valve 160, which is configured to provide selective communication between the back-end transfer module 120 and a load lock chamber of load lock arrangement 130.

The load lock arrangement 130 is further coupled to the EFEM 140 via a load lock gate valve 170. In certain example embodiments, the load lock gate valve 170 is similar to back-end gate valve 160. In that, the load lock gate valve 170 may be configured to permit transfer of one or more substrates between the load lock arrangement 130 and EFEM 140.

The EFEM 140 further includes a front-end substrate transfer robot, which is configured to move within the EFEM 140 for transfer of substrates between one or more load ports 180 and the load lock arrangement 130. The one or more load ports 180 connect to the EFEM 140 and is configured to seat a front opening unified pod (FOUP) housing one or more substrates prior to and subsequent to deposition of material layers onto the substrates. In the example shown in FIG. 2, the system 100 includes three load ports 180. However, in other examples, fewer or additional load ports may be included.

The semiconductor processing system 100 also may comprise a circulation duct system 190 coupled to the EFEM 140. The circulation duct system 190 is illustrated as having a trapezoidal shape, but may have any other shape (e.g., rounded, oval) that does not significantly increase a footprint of the semiconductor processing system 100.

A processor is coupled to the semiconductor processing system 100, for example, through (or over) a wired or wireless link. The processor is operably connected to a user interface and is disposed in communication with a memory. The memory includes a non-transitory machine-readable medium having a plurality of program modules recorded thereon containing instructions that, when read by the processor, cause the processor to execute certain operations.

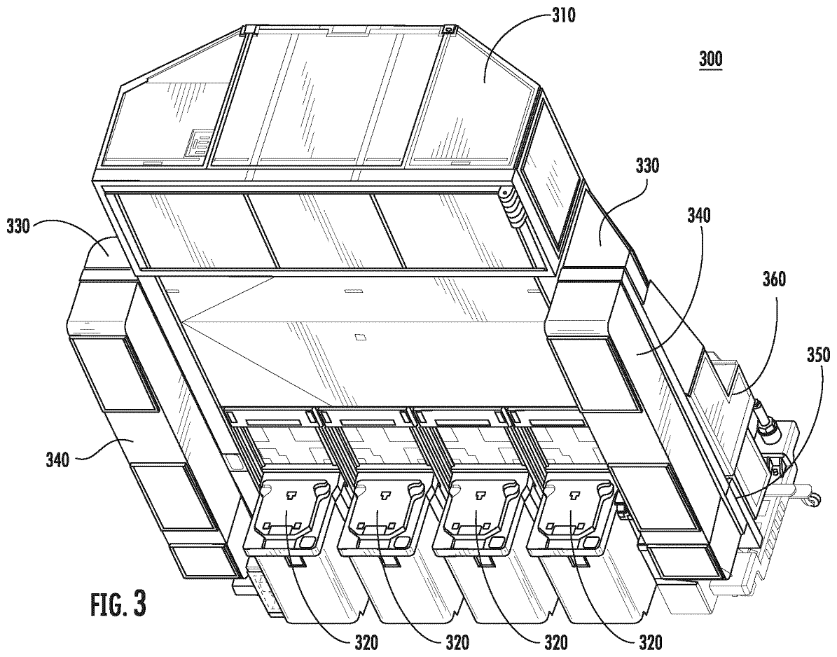

FIG. 3 illustrates an equipment front end module system (EFEM) 300 in accordance with at least one embodiment of the invention. The EFEM 300 may comprise a main body 310, a plurality of load ports 320, an upper duct section 330, a vertical duct section 340, a lower duct section 350, and a cooling station 360. The plurality of load ports 320 are configured to receive a plurality of FOUPs holding a plurality of substrates that are moved to the main body 310 and into a plurality of processing chambers.

The upper duct section 330 and the lower duct section 350 may be coupled to the main body 310. The vertical duct section 340 may be located next to the plurality of load ports 320. The upper duct section 330, the vertical duct section 340, and the lower duct section 350 may be arranged to partially surround the cooling station 360. This arrangement around the cooling station 360 may result in a saving of space, resulting in a smaller overall footprint of the EFEM 300.

The EFEM 300 may also comprise a light curtain. The light curtain may be disposed next to the vertical duct section 340. The light curtain has a function of indicating an alarm situation when an axis of light for the light curtain is blocked.

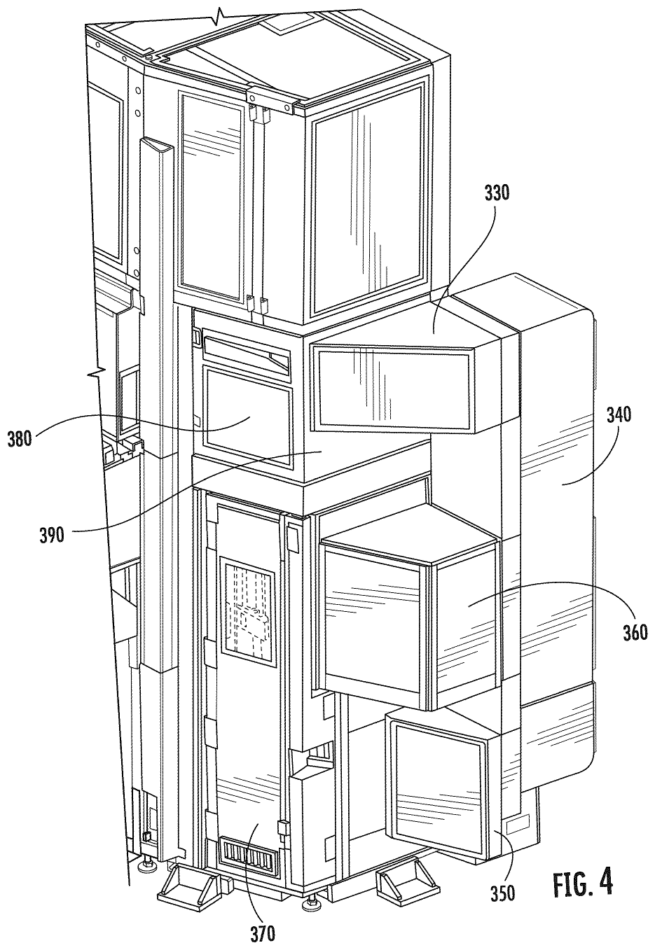

FIG. 4 illustrates a back-side view of a duct assembly in accordance with at least one embodiment of the invention. The duct assembly may comprise an upper duct section 330, a vertical duct section 340, and a lower duct section 350. The duct assembly is illustrated to surround a cooling station 360, similar to FIG. 3.

The lower duct section 350 may be configured to couple to a mini-environment section 370. The mini-environment section 370 may comprise a door that allows access into a mini-environment of the EFEM 300. The mini-environment section 370 may be accessed without removal of the lower duct section 350. An example of a mini-environment is described in U.S. Pat. No. 11,639,811 B2 to Lindeboom et al., which is entitled “Apparatus Including a Clean Mini Environment” and hereby incorporated by reference.

Prior art systems, including the system illustrated in FIG. 1, had the disadvantage of requiring removal of the first duct section 30 or the second duct section 40 in order to access the mini-environment of the EFEM 10. Embodiments of the current invention allow for access without removal of the duct sections, allowing for a quicker maintenance time and a reduced downtime of the semiconductor processing system.

The upper duct section 330 may be coupled to a filter section 380 and a side panel 390. The filter section 380 comprises a door that allows access to a chemical filter. The chemical filter removes pollutants (such as organic, acid, and alkali pollutants) from the N₂ gas that circulates through the main body 310 of the EFEM 300. Replacement of the chemical filter is possible without removal of the upper duct section 330 or separation of the upper duct section 330 from the filter section 380. Removal of the existing chemical filter takes place by opening the door on the filter section 380 and removal of the side panel 390.

Prior art approaches would have required removal of the duct in order to access the chemical filter. By avoiding the removal of the duct, a quicker maintenance time and a reduced downtime of the semiconductor processing system may be achieved. In addition, the chemical filter may be quickly and safely replaced.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A semiconductor processing system, comprising:
one or more load ports configured to hold wafers;
an equipment front end module having a wafer transfer robot to transfer wafers between one or more load ports and a load lock chamber;
a chemical filter configured to filter out a gas flowing through the equipment front end module; and
at least one circulation duct structure coupled to the equipment front end module;
wherein the at least one circulation duct structure is installed at a location proximate to the one or more load ports; and
wherein the chemical filter is unobstructed by the at least one circulation duct structure.

2. The semiconductor processing system of claim 1, wherein the at least one circulation duct structure comprises an upper duct section, a vertical duct section, and a lower duct section.

3. The semiconductor processing system of claim 2, wherein the upper duct section couples to a filter section of the equipment front end module, and wherein the filter section comprises a door for accessing the chemical filter without removal of the upper duct section from the equipment front end module.

4. The semiconductor processing system of claim 2, wherein the equipment front end module comprises a mini-environment door, wherein the mini-environment door is unobstructed by the at least one circulation duct.

5. The semiconductor processing system of claim 1, wherein the one or more load ports includes a plurality of load ports.

6. The semiconductor processing system of claim 2, wherein the vertical duct section is located proximate to the one or more load ports.

7. The semiconductor processing system of claim 1, further comprising:
a first plurality of gate valves configured to connect the equipment front end module to the load lock chamber;
a back end wafer handling chamber configured to receive at least one wafer from the load lock chamber;
at least one process module configured to process a wafer;
a second plurality of gate valves configured to connect the load lock chamber to the back end wafer handling chamber; and
a third plurality of gate valves configured to connect the back end wafer handling chamber to the at least one process module.

8. The semiconductor processing system of claim 7, wherein the at least one process module comprises at least one of: a single chamber configuration, a dual chamber configuration, or a quad chamber configuration.

9. The semiconductor processing system of claim 7, wherein the at least one process module is configured to process a wafer according to at least one of: an atomic layer deposition (ALD) process, a plasma enhanced atomic layer deposition (PEALD) process, a chemical vapor deposition (CVD) process, a plasma enhanced chemical vapor deposition (PECVD) process, an epitaxial deposition process, or a physical vapor deposition (PVD) process.

10. A duct assembly comprises:
an equipment front end module (EFEM) having a wafer transfer robot to transfer wafers between one or more load ports and a load lock chamber, wherein the EFEM comprises:
a filter section configured to hold a chemical filter; and
a mini-environment door;
an upper duct section coupled to the filter section;
a vertical duct section coupled to the upper duct section and located proximate to the one or more load ports; and
a lower duct section coupled to the vertical duct section, wherein the lower duct section is located proximate to the mini-environment door,
wherein the chemical filter can be replaced without separation of the upper duct section from the filter section.

11. The duct assembly of claim 10, wherein the vertical duct section is located proximate to the one or more load ports.

12. The duct assembly of claim 10, further comprising:
a first plurality of gate valves configured to connect the EFEM to the load lock chamber.

13. The duct assembly of claim 10, wherein the one or more load ports are configured to receive a front end unified pod (FOUP).

14. The duct assembly of claim 10, wherein the one or more load ports includes a plurality of load ports.
